(19) United States
(12) Patent Application Publication
(10) Pub. No.: US 2008/0000675 A1
(43) Pub. Date: Jan. 3, 2008

(54) SYSTEM AND METHOD OF PROVIDING STRUCTURAL SUPPORT TO PRINTED WIRING ASSEMBLY COMPONENTS

(75) Inventors: John Fredy Arroyave, Tampa, FL (US); Michael James Gillespie, Seminole, FL (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/428,053

(22) Filed: Jun. 30, 2006

(51) Int. Cl. H05K 1/16

(52) U.S. Cl. 174/260

(57) ABSTRACT

A printed wiring assembly is provided. The printed wiring assembly comprises a printed wiring board, at least one surface mounted component coupled to a surface of the printed wiring board, and at least one support device coupled to the printed wiring board and to the at least one surface mounted component, wherein the at least on surface mounted component is adapted to limit movement of the at least one surface mounted component when the assembly is subject to vibration environments.

### BACKGROUND

Surface Mount Technology (SMT) is a technology used in producing printed wiring assemblies where the components are coupled directly to the surface of a printed wiring board. Through-hole technology is another method of producing printed wiring assemblies by inserting leads connected to components through holes in a printed circuit board to couple the components to the printed circuit board. SMT technology has increasingly replaced through-hole technology in the production of electronic circuits due, in part, to the typically smaller printed wiring assemblies associated with SMT technology. For example, SMT components typically have smaller or no leads than the leads on components used in through-hole technology. In addition to being smaller, SMT components often weigh less than through-hole components. These are two important advantages leading to the use of SMT technology.

Situations arise, however, in which tall SMT components are needed. The taller the SMT components the center of gravity of the SMT components becomes further removed from the printed circuit board. As the center of gravity becomes further removed, the SMT components are more easily moved by accelerations caused by shock, sinusoidal, or random vibrations which can damage the SMT component leads or the SMT component itself. One conventional solution to protect the SMT components is to apply epoxy to the SMT component ends. However, due in part to the viscosities of epoxy, epoxy does not form a stiff enough support to provide sufficient protection of the SMT components during vibration environments. Printed wiring assemblies used in mobile products, such as aircraft, spacecraft, satellites, etc., particularly need sufficient protection for the SMT components, since these products undergo strong vibration environments during normal operation.

For the reasons stated above, and for other reasons stated below which will become apparent to those skilled in the art upon reading and understanding the present specification, there is a need in the art for better protection of SMT components from damage due to vibration environments.

### SUMMARY

The above-mentioned problems and other problems are resolved by the present invention and will be understood by reading and studying the following specification.

In one embodiment, a printed wiring assembly is provided. The printed wiring assembly comprises a printed wiring board, at least one surface mounted component coupled to a surface of the printed wiring board, and at least one support device coupled to the printed wiring board and to the at least one surface mounted component, wherein the at least one surface mounted component is adapted to limit movement of the at least one surface mounted component when the assembly is subject to vibration environments.

In another embodiment, a support device for a surface mounted component on a printed wiring board is provided. The support device comprises a brace having a first side adapted to be coupled to the printed wiring board and a second side adapted to be coupled to the surface mounted component such that the brace limits movement of the surface mounted component on the printed wiring board when the surface mounted component and printed wiring board are subject to vibration environments.

In another embodiment, a method of assembling a printed wiring assembly is provided. The method comprises coupling at least one surface mounted component to a printed wiring board and coupling at least one support device to the at least one surface mounted component and the printed wiring board, wherein the at least one support device is adapted to limit movement of the at least one surface mounted component along at least one axis when the assembly is subject to vibration environments.

### DRAWINGS

The present invention can be more easily understood and further advantages and uses thereof more readily apparent, when considered in view of the description of the following figures in which:

FIG. 1 is a front view of a printed wiring assembly according to one embodiment of the present invention

FIG. 2 is a top view of a printed wiring assembly according to one embodiment of the present invention.

FIG. 3 is a side view of a printed wiring assembly according to one embodiment of the present invention.

FIG. 4 is a flow chart showing a method of assembling a printed wiring assembly according to one embodiment of the present invention.

Like reference numbers and designations in the various drawings indicate like elements.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the scope of the present invention. It should be understood that the exemplary method illustrated may include additional or fewer steps or may be performed in the context of a larger processing scheme. Furthermore, the method presented in the drawing figures or the specification is not to be construed as limiting the order in which the individual steps may be performed. The following detailed description is, therefore, not to be taken in a limiting sense.

Embodiments of the present invention protect surface mounted components from damage due to vibration during operation. This is accomplished by providing support devices coupled to surface mounted components and the printed wiring board. In addition, the support devices are adapted to provide an additional benefit of transferring heat away from the surface mounted components and to the printed wiring board, in some embodiments. As used herein, “vibration environments” includes, but is not limited to, random vibration, sinusoidal vibration, and shock.

In describing FIGS. 1-3, a 3-dimensional coordinate axis system is employed. With reference to FIGS. 1-3, the Z axis refers to the axis running in the direction from a printed wiring board to the top of a surface mounted component. Also with reference to FIGS. 1-3, the X axis refers to an axis orthogonal to the Z axis and running in a direction parallel to a side of a surface mounted component having component leads. Finally, with reference to FIGS. 1-3, the Y axis refers to an axis orthogonal to the Z and X axes.

FIG. 1 is a front view of a printed wiring assembly 100 according to one embodiment of the present invention. Printed wiring assembly (PWA) 100 includes surface mounted component 102 with leads 104, printed wiring board (PWB) 106, and support devices 108-1 and 108-2. Although two support devices 108 are shown in FIG. 1, it is to be understood that, in other embodiments, any appropriate number of support devices 108 are used. Support devices 108-1 and 108-2 are braces coupled to component 102 and PWB 106. As can be seen in FIG. 1, support devices 108-1 and 108-2 help limit movement of component 102 along the X axis. In addition, since support devices 108-1 and 108-2 are coupled to PWB 106, support devices 108-1 and 108-2 also help limit movement along the Y and Z axes via connectors 110.

In this exemplary embodiment, connectors 110 are thermally conductive epoxy. However, in other embodiments, connectors 110 are comprised of other materials. For example, in one embodiment, solder pads are placed on component 102 and PWB 106 so that metal solder is used for connectors 110. In addition, support devices 108-1 and 108-2 are made of metal in this example. In particular, support devices 108-1 and 108-2, in this example, are made of aluminum. However, it is to be understood that in other embodiments, other metals are used, such as copper, silver, etc. By using a thermally conductive epoxy and metal braces, embodiments of the present invention are also able to conduct heat away from component 102 and into PWB 106 via connectors 110 and support devices 108-1 and 108-2. However, it is not required to use a thermally conductive metal for support devices 108-1 and 108-2 or a thermally conductive epoxy for connectors 110.

With regards to the shape of support devices 108-1 and 108-2, as can be seen in the example in FIG. 1, support devices 108-1 and 108-2 are wedge shaped. In addition, support device 108-2 has a hollow center 112. Having a hollow center 112 reduces the weight of support device 108-2. Also, hollow center 112 increases the surface area of support device 108-2 which is in contact with air. When used in embodiments which come in contact with air, the increased surface area improves the transfer of heat to air via support device 108-2. In other embodiments, other means of increasing surface area are used, such as placing holes in support device 108-2. Notably, although support devices 108-1 and 108-2 are wedged shaped in this example, embodiments of the present invention are not intended to be so limited. In particular, support devices 108-1 and 108-2 have other shapes, such as L-shapes, block shapes, etc.

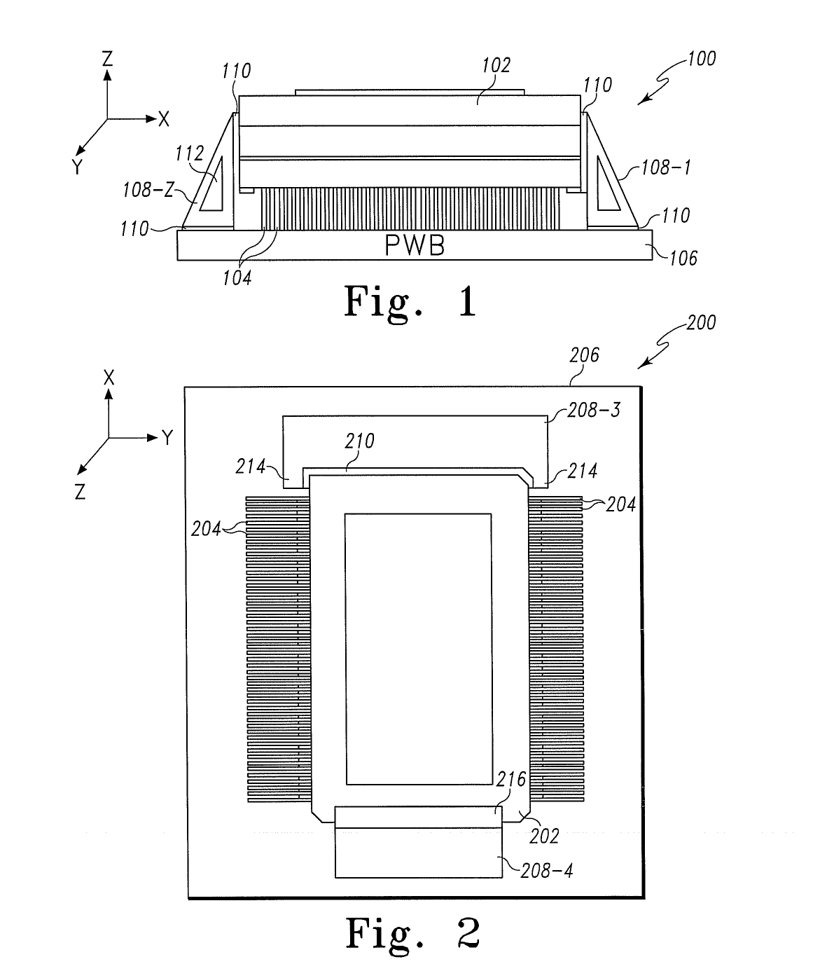

FIG. 2 is a top view of a printed wiring assembly 200 according to one embodiment of the present invention. PWA 200 includes PWB 206, surface mount component 202 with leads 204, and support devices 208-3 and 208-4. Support devices 208-3 and 208-4 are coupled to component 202 via connectors 210. In this exemplary embodiment, connectors 210 are thermally conductive epoxy. However, in other embodiments, connectors 210 are comprised of other materials. For example, in one embodiment, solder pads are placed on component 202 and metal solder is used for connectors 210.

Support devices 208-3 and 208-4 are made of metal in this example. In particular, support devices 208-3 and 208-4, in this example, are made of aluminum. However, it is to be understood that in other embodiments, other metals are used, such as copper, silver, etc. By using a thermally conductive epoxy and metal braces, embodiments of the present invention are also able to conduct heat away from component 202 via connectors 210. However, it is not required to use a thermally conductive metal for support devices 208-3 and 208-4 or a thermally conductive epoxy for connectors 210.

As with support devices 108-1 and 108-2 in FIG. 1, support devices 208-3 and 208-4 also limit movement of component 202 along the X axis. In addition, support device 208-3 is adapted with flanges 214. Flanges 214 overlap edges on sides of component 202 in order to help support device 208-3 limit movement of component 202 along the Y axis as well. Similarly, support device 208-4 is adapted with flange 216. Flange 216 overlaps a top edge of component 202 in order to help support device 208-4 limit movement of component 202 along the Z axis.

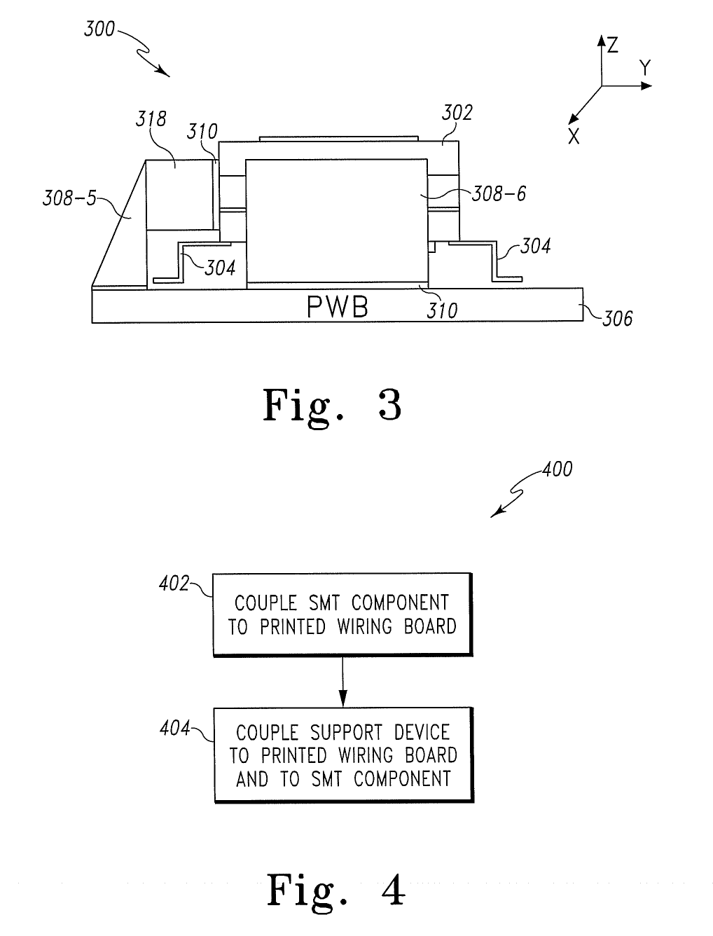

FIG. 3 is a side view of a printed wiring assembly 300 according to one embodiment of the present invention. PWA 300 includes surface mount component 302 with leads 304, PWB 306, and support devices 308-5 and 308-6. Support devices 308-5 and 308-6 are coupled to component 302 and PWB 306 via connectors 310. In this exemplary embodiment, connectors 310 are thermally conductive epoxy. However, in other embodiments, connectors 310 are comprised of other materials. For example, in one embodiment, solder pads are placed on component 302 and metal solder is used for connectors 310.

Support devices 308-5 and 308-6 are made of metal in this example. In particular, support devices 308-5 and 308-6, in this example, are made of aluminum. However, it is to be understood that in other embodiments, other metals are used, such as copper, silver, etc. By using a thermally conductive epoxy and metal braces, embodiments of the present invention are also able to conduct heat away from component 302 via connectors 310. However, it is not required to use a thermally conductive metal for support devices 308-5 and 308-6 or a thermally conductive epoxy for connectors 310. In addition, as can be seen in FIG. 3, support device 308-5 is wedge shaped in this example. However, in other embodiments, other shapes are used. For example, in other embodiments support device 308-5 is L-shaped, block shaped, or the like.

As with support devices 108-1 and 108-2, support device 308-6 also limits movement of component 302 along the X axis. Support device 308-5 aids in impeding movement of component 302 via its connection to component 302 and PWB 306 with connectors 310. The strength of this aid is based in part on the shearing and adhesive strength of connectors 310. In addition, support device 308-5 is adapted with extension 318. Extension 318 enables support device 308-5 to make contact with component 302 without contacting leads 304. In this way, support device 308-5 is able to be placed on sides of component 302 having leads 304. In this example, support device 308-5 limits movement of component 302 along the Y axis. However, in other embodiments, support devices on other sides of component 302 are also adapted with extension 318. For example, in some embodiments, component 302 is a quad flat package (QFP) with leads 304 extending from all four sides of component 302. In such embodiments, extension 318 is used with each support device to make contact with component 302 without contacting leads 304. Finally, as shown in FIG. 3, extension 318 is formed as an integral part of support device 308-5. However, in other embodiments, extension 318 is connected to support device 308-5 via a connector, such as connector 310.

FIG. 4 is a flow chart showing a method 400 of assembling a printed wiring assembly according to one embodiment of the present invention. At 402, at least one surface mount component, such as component 102 in FIG. 1, is coupled to a printed wiring board, such as PWB 106 in FIG. 1. At 404, at least one support device, such as support device 108-1 in FIG. 1, is coupled to the printed wiring board and to at least one component. The at least one support device is adapted to limit movement of the at least one surface mounted component along at least one axis, as described above. In some embodiments, the at least one support device is coupled to the printed wiring board and at least one component with thermally conductive epoxy. However, in other embodiments, other ways of coupling at least one support device are used. For example, in some embodiments, at least one support device is soldered to the component and the printed wiring board.

In addition, coupling at least one support device to the surface mounted component includes coupling at least one support device on two or more sides of the component, in some embodiments. For example, in one embodiment, two shorter support devices are coupled on one side of a component to reduce the weight that is used by one longer support device. Coupling a support device to a surface mounted component also includes, in some embodiments, coupling a support device such that the support device overlaps one or more edges of the surface mounted component (see support devices 208-3 and 208-4 in FIG. 2). An extension, such as extension 318 in FIG. 3, is also used, in another embodiment, to couple the support device to a side of the surface mounted components having a plurality of leads. The extension spans a gap over the leads between the surface mounted component and the support device enabling the support device to couple to the surface mounted component without contacting the leads. In some embodiments, the extension is coupled to each of the surface mounted component and the support device with an adhesive, such as epoxy or solder. Alternatively, the extension is an integral member of the support device and only coupled to the surface mounted component with an adhesive.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed is:

1. A printed wiring assembly, comprising:
a printed wiring board;
at least one surface mounted component coupled to a surface of the printed wiring board; and
at least one support device coupled to the printed wiring board and to the at least one surface mounted component, wherein the at least one surface mounted component is adapted to limit movement of the at least one surface mounted component when the assembly is subject to vibration environments.

2. The printed wiring assembly of claim 1, wherein the at least one support device is coupled to the at least one surface mounted component and to the printed wiring board with a thermally conductive epoxy.

3. The printed wiring assembly of claim 1, wherein the at least one support device is made of one of copper and aluminum.

4. The printed wiring assembly of claim 1, wherein the at least one support device is soldered to the at least one surface mounted component and to the printed wiring board.

5. The printed wiring assembly of claim 1, wherein the at least one support device has a hollow center.

6. The printed wiring assembly of claim 1, wherein the at least one support device is further adapted to overlap one or more edges of the at least one surface mounted component.

7. The printed wiring assembly of claim 1, wherein the at least one support device is one of wedge shaped, L-shaped, and block shaped.

8. The printed wiring assembly of claim 1, wherein the at least one support device further comprises at least one support device on each of two or more sides of the at least one surface mounted component.

9. The printed wiring assembly of claim 1, wherein the at least one support device further comprises an extension such that the at least one support device, when placed on a side of the at least one surface mounted component having leads, contacts the at least one surface mounted component without contacting the leads.

10. A support device for a surface mounted component on a printed wiring board, comprising:
a brace having a first side adapted to be coupled to the printed wiring board and a second side adapted to be coupled to the surface mounted component such that the brace limits movement of the surface mounted component on the printed wiring board when the surface mounted component is subject to vibration environments.

11. The support device of claim 10 wherein the brace is one of wedge shaped, L-shaped, and block shaped.

12. The support device of claim 10, wherein the brace is made of one of copper and aluminum.

13. The support device of claim 10, wherein the brace is further adapted with an extension such that the brace, when placed on a side of the surface mounted component having leads, contacts the surface mounted component without contacting the leads.

14. The support device of claim 10, wherein the brace has a hollow center.

15. The support device of claim 10, wherein the brace is further adapted with one or more flanges to overlap one or more edges of the surface mounted component.

16. A method of assembling a printed wiring assembly, the method comprising:
coupling at least one surface mounted component to a printed wiring board; and
coupling at least one support device to the at least one surface mounted component and the printed wiring board, wherein the at least one support device is adapted to limit movement of the at least one surface mounted component along at least one axis when the assembly is subject to vibration environments.

17. The method of claim 16, wherein coupling the at least one support device to the at least one surface mounted component and the printed wiring board further comprises one of:
coupling at least one support device to the at least one surface mounted component and the printed wiring board with thermally conductive epoxy; and
soldering at least one support device to the at least one surface mounted component and the printed wiring board.

18. The method of claim 16, wherein coupling the at least one support device to the at least one surface mounted component and the printed wiring board further comprises coupling at least one support device on two or more sides of the at least one surface mounted component.

19. The method of claim 16, wherein coupling the at least one support device to the at least one surface mounted component and the printed wiring board further comprises coupling the at least one support device to the at least one surface mounted component such that a portion of the at least one support device overlaps one or more edges of the at least one surface mounted component.

20. The method of claim 16, wherein coupling the at least one support device to the at least one surface mounted component further comprises coupling an extension between the at least one surface mounted component and the at least one support device, wherein the extension is coupled over a plurality of surface mounted component leads such that the at least one support device is coupled to the at least one surface mounted component without contacting the plurality of leads.
